(19) United States
(12) Patent Application Publication
(10) Pub. No.: US 2026/0136743 A1
(43) Pub. Date: May 14, 2026

(54) Light-Emitting Substrate, Backlight Source and Display Apparatus

(71) Applicants: BOE MLED Technology Co., Ltd., Beijing (CN); BOE Technology Group Co., Ltd., Beijing (CN)

(72) Inventors: Honghao Yu, Beijing (CN); Donglei Li, Beijing (CN); Kun Lu, Beijing (CN); Tonghua Yang, Beijing (CN); Yong Li, Beijing (CN); Jiaxin Li, Beijing (CN); Dongdong Ma, Beijing (CN); Yufan Mu, Beijing (CN)

(73) Assignees: BOE MLED Technology Co., Ltd., Beijing (CN); BOE Technology Group Co., Ltd., Beijing (CN)

(21) Appl. No.: 18/846,597

(22) PCT Filed: Sep. 27, 2023
(86) PCT No.: PCT/CN2023/121993

§ 371 Date: Sep. 12, 2024

(51) Int. Cl. H10H 29/853; H10H 29/37; H10H 29/856

(52) U.S. Cl. CPC H10H 29/853; H10H 29/37; H10H 29/856

(57) ABSTRACT

A light-emitting substrate, a backlight source and a display apparatus are provided. The light-emitting substrate includes a substrate, and a plurality of light-emitting units and a light-transmission protective structure disposed on the substrate. The substrate includes a plurality of dimming partitions; and the light-transmission protective structure wraps the plurality of light-emitting units, except for portions in contact with the substrate. Each dimming partition includes at least one light-emitting unit, the light-transmission protective structure includes a plurality of sub-protective structure groups disposed in one-to-one correspondence with the plurality of dimming partitions, each sub-protective structure group wraps the light-emitting unit in one dimming partition, and adjacent sub-protective structure groups corresponding to at least two adjacent dimming partitions are integrated. Each dimming partition is provided with one sub-protective structure group, and adjacent sub-protective structure groups corresponding to at least two adjacent dimming partitions are integrated.

### TECHNICAL FIELD

Embodiments of the present disclosure relate to a light-emitting substrate, a backlight source and a display apparatus.

### BACKGROUND

In backlight products that use sub-millimeter light-emitting diodes (mini LEDs) as light-emitting elements, optical structures may be disposed on light exit sides of the light-emitting elements to optimize the pattern of light emitted from the light-emitting elements.

### SUMMARY

The present disclosure provides a light-emitting substrate, a backlight source and a display apparatus.

An embodiment of the present disclosure provides a light-emitting substrate, which includes: a substrate, and a plurality of light-emitting units and a light-transmission protective structure located on the substrate. The substrate includes a plurality of dimming partitions; the light-transmission protective structure wraps the plurality of light-emitting units, except for portions in contact with the substrate. Each dimming partition includes at least one light-emitting unit, the light-transmission protective structure includes a plurality of sub-protective structure groups disposed in one-to-one correspondence with the plurality of dimming partitions, each sub-protective structure group wraps the light-emitting unit in one dimming partition, and adjacent sub-protective structure groups corresponding to at least two adjacent dimming partitions are integrated.

For example, according to an embodiment of the present disclosure, each sub-protective structure group comprises at least one sub-protective structure, the number of the sub-protective structures is the same as the number of the plurality of light-emitting units, the sub-protective structures and the plurality of light-emitting units are disposed in one-to-one correspondence, and at least some of the sub-protective structures are integrated.

For example, according to an embodiment of the present disclosure, the sub-protective structures corresponding to the same dimming partition are integrated.

For example, according to an embodiment of the present disclosure, a surface of the sub-protective structure away from the substrate has a point with a greatest distance from the substrate, a distance between an orthographic projection of the point on the substrate and a center of an orthographic projection, on the substrate, of the light-emitting unit covered by the sub-protective structure is not greater than 2% of a maximum size of the orthographic projection of the light-emitting unit.

For example, according to an embodiment of the present disclosure, a surface on a side that is of the integrated adjacent sub-protective structures and that is away from the substrate comprises a concave portion curving toward a side close to the light-emitting unit, and the concave portion is located between adjacent light-emitting units.

For example, according to an embodiment of the present disclosure, a contour of an orthographic projection, on the substrate, of the light-transmission protective structure comprises a plurality of curved segments connected in sequence, each curved segment curves to a side away from a center of the orthographic protection of the light-transmission protective structure, and a distance between at least one endpoint of the curved segment and the center of the orthographic protection of the light-transmission protective structure is less than a distance between another point of the curved segment and the center of the orthographic protection of the light-transmission protective structure.

For example, according to an embodiment of the present disclosure, at least one curved segment is an arc segment, a radius of a circle in which the arc segment is located is r, a distance between centers of adjacent light-emitting units is L, and L and r satisfy a relation equation: L/2≤r≤L.

For example, according to an embodiment of the present disclosure, at least some of the curved segments are arc segments, and radii of circles where the arc segments are located are r; the plurality of light-emitting units is arranged in an array along a first direction and a second direction, the first direction is perpendicular to the second direction, a pitch of the light-emitting units arranged in the first direction is a first pitch p1, a pitch of the light-emitting units arranged in the second direction is a second pitch p2, the first pitch is not less than the second pitch, and p1 and r satisfy a relation equation: {[(p1)²+(p2)²]^{1/2}}/2≤r≤p1.

For example, according to an embodiment of the present disclosure, the plurality of light-emitting units is arranged in an array along a first direction and a second direction, the first direction intersects the second direction, a minimum distance between the concave portion disposed between adjacent light-emitting units arranged in the first direction and the substrate is a first distance, a minimum distance between the concave portion disposed between adjacent light-emitting units arranged in the second direction and the substrate is a second distance, and a ratio of the first distance to the second distance is 0.95-1.05.

For example, according to an embodiment of the present disclosure, the plurality of light-emitting units includes adjacent light-emitting units arranged in a third direction, the first direction and the second direction both intersect the third direction, a minimum distance between the concave portion disposed between adjacent light-emitting units arranged in the third direction and the substrate is a third distance, and the first distance is greater than the third distance.

For example, according to an embodiment of the present disclosure, the plurality of light-emitting units is arranged in an array along a first direction and a second direction, the plurality of light-emitting units has a spacing in the first direction equal to that of the plurality of light-emitting units in the second direction, the plurality of sub-protective structures is of an integrated structure, and a surface of the light-transmission protective structure away from the substrate comprises a free-form surface.

For example, according to an embodiment of the present disclosure, in at least some of the dimming partitions, there is a gap between adjacent sub-protective structure groups corresponding to adjacent dimming partitions, and a surface on a side that is of the same sub-protective structure group and that is away from the substrate comprises a concave portion curving toward a side close to the light-emitting unit, and the concave portion is located between adjacent light-emitting units.

For example, according to an embodiment of the present disclosure, the plurality of light-emitting units includes peripheral light-emitting units closest to the contour of the orthographic protection, on the substrate, of the light-transmission protective structure, and the number of the plurality of curved segments is the same as the number of the peripheral light-emitting units.

For example, according to an embodiment of the present disclosure, the curved segments include arc segments, and degrees of central angles of circles where the arc segments are located are not greater than 280 degrees.

For example, according to an embodiment of the present disclosure, the light-emitting substrate further includes: a reflection pattern comprising openings and a reflection layer surrounding the openings. The openings are configured to expose the light-emitting units, and along a direction perpendicular to the substrate, the reflection layer overlaps the light-transmission protective structure and is located between the light-transmission protective structure and the substrate.

For example, according to an embodiment of the present disclosure, the light-emitting substrate further includes a driver chip configured to control at least one dimming partition, the reflection layer covering the driver chip.

For example, according to an embodiment of the present disclosure, a material of the light-transmission protective structure comprises organosilicon, and the light-transmission protective structure has a refractive index of 1.3-1.7 and a transmittance rate of greater than 80%.

For example, according to an embodiment of the present disclosure, the light-emitting unit emits light at a wavelength of 430-480 nanometers, and the light-transmission protective structure comprises an inorganic luminescent material.

For example, according to an embodiment of the present disclosure, the light-emitting unit comprises an unpackaged light-emitting diode chip, and the unpackaged light-emitting diode chip has a maximum size of not greater than 500 micrometers in a direction parallel to the substrate.

Another embodiment of the present disclosure provides a backlight source, which includes any light-emitting substrate as mentioned above.

Another embodiment of the present disclosure provides a display apparatus, which includes any light-emitting substrate as mentioned above.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1A is a planar view of one dimming partition of a general light-emitting substrate.

FIG. 1B is a luminance distribution diagram of the dimming partition shown in FIG. 1A.

FIG. 1C is a partial planar view of the general light-emitting substrate including a plurality of dimming partitions shown in FIG. 1A.

FIG. 1D is a luminance distribution diagram of the plurality of dimming partitions shown in FIG. 1C.

FIG. 1E is a superimposed view of the plurality of dimming partitions shown in FIG. 1C and the luminance distribution diagram, shown in FIG. 1D, corresponding to the dimming partitions shown in FIG. 1C.

FIG. 2 is a schematic diagram of a planar structure of a light-emitting substrate according to an embodiment of the present disclosure.

FIG. 3 is a schematic diagram of a partial cross-sectional structure cut along line AA′ shown in FIG. 2.

FIG. 4 is a schematic diagram of a partial cross-sectional structure cut along line BB′ shown in FIG. 2.

FIG. 5 is a schematic diagram of a partial cross-sectional structure cut along line CC′ shown in FIG. 2.

FIG. 6 is a schematic diagram of a partial planar structure of a light-emitting substrate according to another example of an embodiment of the present disclosure.

FIG. 7 is a schematic diagram of a partial cross-sectional structure cut along line EE′ shown in FIG. 6.

FIG. 8 is a schematic diagram of a planar structure of a light-emitting substrate according to another example of an embodiment of the present disclosure.

FIG. 9 is a luminance distribution diagram of one dimming partition shown in FIG. 8.

FIG. 10 is a luminance distribution diagram of a plurality of dimming partitions shown in FIG. 8.

FIG. 11 is a superimposed view of the plurality of dimming partitions shown in FIG. 8 and the luminance distribution diagram, shown in FIG. 10, corresponding to the dimming partitions shown in FIG. 8.

FIG. 12 is a partial cross-sectional view of a light-emitting substrate according to another example of an embodiment of the present disclosure.

FIG. 13 is a schematic diagram of a partial cross-sectional structure of a backlight source according to another embodiment of the present disclosure.

FIG. 14 is a schematic diagram of a partial cross-sectional structure of a display apparatus according to another embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The features “parallel”, “perpendicular” and “same” used in the embodiments of the present disclosure all include features such as “parallel”, “perpendicular” and “same” in the strict sense, and the cases having certain errors, such as “approximately parallel”, “approximately perpendicular”, “approximately the same” or the like, taking into account measurements and errors associated with the measurement of a particular quantity (e.g., limitations of the measurement system), and indicate being within an acceptable range of deviation for a particular value as determined by one of ordinary skill in the art. For example, “approximately” may indicate being within one or more standard deviations, or within 10% or 5% of the stated value. In the case that the quantity of a component is not specifically indicated below in the embodiments of the present disclosure, it means that the component may be one or more, or may be understood as at least one. “At least one” means one or more, and “plurality” means at least two.

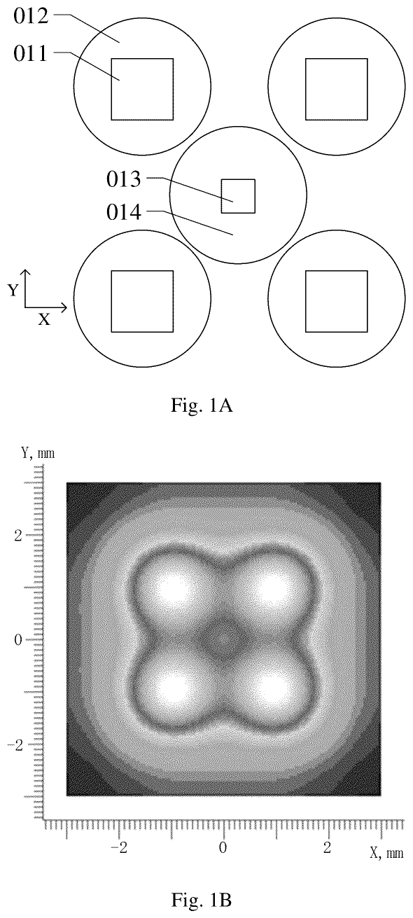

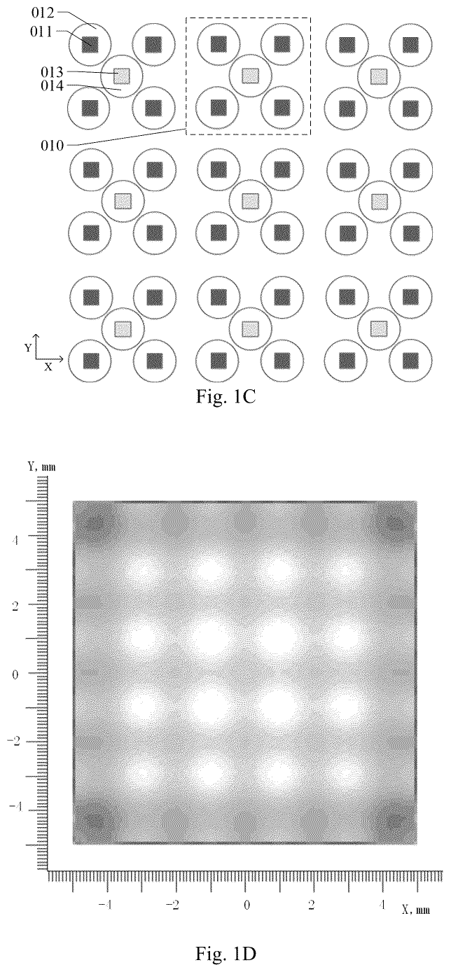

FIG. 1A is a planar view of one dimming partition 010 of a general light-emitting substrate. As shown in FIG. 1A, the light-emitting substrate includes a light-emitting element 011, a first encapsulation portion 012 covering the light-emitting element, a driver element 013 that drives the light-emitting element to emit light, and a second encapsulation portion 014 covering the driver element 013. FIG. 1B is a luminance distribution diagram of the dimming partition shown in FIG. 1A. FIG. 1C is a partial planar view of the general light-emitting substrate including a plurality of dimming partitions shown in FIG. 1A. FIG. 1D is a luminance distribution diagram of the plurality of dimming partitions shown in FIG. 1C. FIG. 1E is a superimposed view of the plurality of dimming partitions shown in FIG. 1C and the luminance distribution diagram, shown in FIG. 1D, corresponding thereto. In the respective luminance distribution diagrams of the present disclosure, the position of a lighter color has a stronger luminance and the position of a darker color has a weaker luminance. For example, the closer to the edge of a detection region in each diagram, the weaker luminance the position has.

In the study, the inventors of the present application found that: in order to ensure a complete pattern of light emitted from a single light-emitting element through the first encapsulation portion, it is necessary to ensure that there is no design of overlap between the first encapsulation portion corresponding to each light-emitting element and the first encapsulation portion corresponding to the adjacent light-emitting element. When the driver element is covered with the second encapsulation portion, in order to achieve the complete pattern of light emitted from the single light-emitting element through the first encapsulation portion, it is necessary to ensure that there is no overlap between the first encapsulation portion corresponding to each light-emitting element and the second encapsulation portion corresponding to the driver element. For example, FIG. 1A schematically shows the second encapsulation portion 014 having a circular orthographic projection. However, this embodiment is not limited thereto, the shape of an orthographic projection of the second encapsulation portion 014 may be an oval, a polygon, and other shapes, or may be similar to the shape of an orthographic projection of the driver element 013, as long as the second encapsulation portion 014 is able to cover the driver element 013. For example, the maximum size of the orthographic projection of the second encapsulation portion 014 may be smaller than the maximum size of an orthographic projection of the first encapsulation portion 012.

FIG. 1A and FIG. 1C show that the first encapsulation portion 012 is made of, for example, transparent silicone. Specifically, the first encapsulation portion 012 is formed by spraying high-thixotropic transparent silicone glue via a glue dispenser to the area where the light-emitting element is located and then curing. Because each light-emitting element corresponds to one first encapsulation portion, in order to avoid affecting the pattern of light emitted from a single light-emitting element due to mutual interference of the adjacent first encapsulation portions, a pitch P of adjacent light-emitting elements needs to be restricted. Therefore, the above design cannot meet requirements of the light-emitting substrate having a plurality of light-emitting elements arranged in an array with a smaller pitch P. The above-mentioned pitch refers to a length of a line connecting centers of two adjacent light-emitting elements arranged in an X-direction or a Y-direction, such as a distance between the geometric centers of the two.

For example, as shown in FIG. 1A, the light-emitting element 011 has a dimension a in the X-direction and a dimension b in the Y-direction, the orthographic projection of the first encapsulation portion 012 is a circle with a radius of R, and the pitches between the adjacent light-emitting elements 011 arranged in the X-direction and the adjacent light-emitting elements 011 arranged in the Y-direction are P. In the case where the light-emitting substrate is not provided with the driver element 013, a, b, R, and P satisfy the relation equation: {[(a)²+(b)²]^{1/2}}/2≤R≤P/2. In the case where the light-emitting substrate is provided with the driver element 013, the driver element 013 is located in a region where the light-emitting elements 011 are arranged in an array along a manner of 2*2, and when the orthographic projections of the second encapsulation portion 014 and the first encapsulation portion 012 are circles with the same radius, a, b, R, and P satisfy the relation equation: {[(a)²+(b)²]^{1/2}}/2≤R≤(2^{1/2}*P)/4.

The present disclosure provides a light-emitting substrate, a backlight source and a display apparatus. The light-emitting substrate includes a substrate, and a plurality of light-emitting units and a light-transmission protective structure that are disposed on the substrate. The substrate includes a plurality of dimming partitions; and the light-transmission protective structure wraps the plurality of light-emitting units, except for portions in contact with the substrate. Each dimming partition includes at least one light-emitting unit, the light-transmission protective structure includes a plurality of sub-protective structure groups disposed in one-to-one correspondence with the plurality of dimming partitions, each sub-protective structure group wraps the light-emitting unit in one dimming partition, and adjacent sub-protective structure groups corresponding to at least two adjacent dimming partitions are integrated.

In the light-emitting substrate provided in the present disclosure, each dimming partition is provided with one sub-protective structure group wrapping the light-emitting unit within the dimming partition, and adjacent sub-protective structure groups corresponding to at least two adjacent dimming partitions are integrated, so that the pitch of the light-emitting unit is not subject to the dimensional limitation of the light-transmission protective structure and has a higher design freedom, the modulation of light from each dimming partition in all directions and the optimized control of the overall light pattern can be realized, and the matching with a dynamic local dimming algorithm can also be achieved, making the light-emitting substrate have a better light uniformization effect.

The following describes, with reference to the accompanying drawings, the light-emitting substrate and the display apparatus provided in embodiments of the present disclosure.

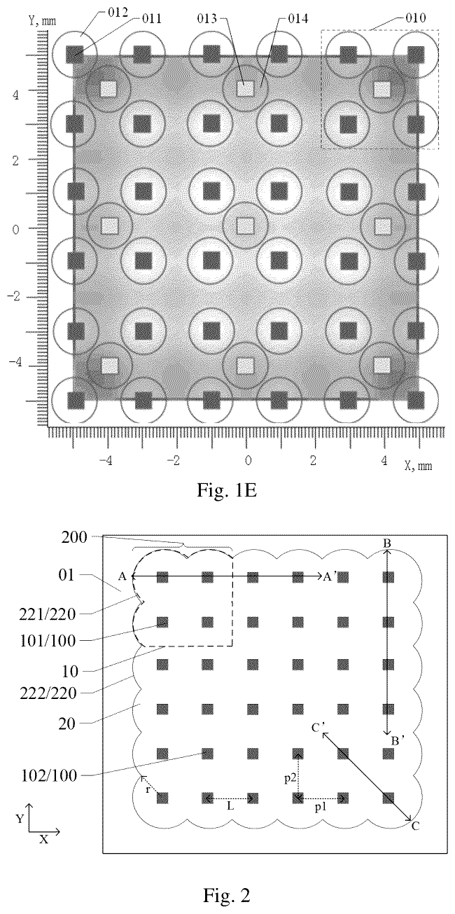

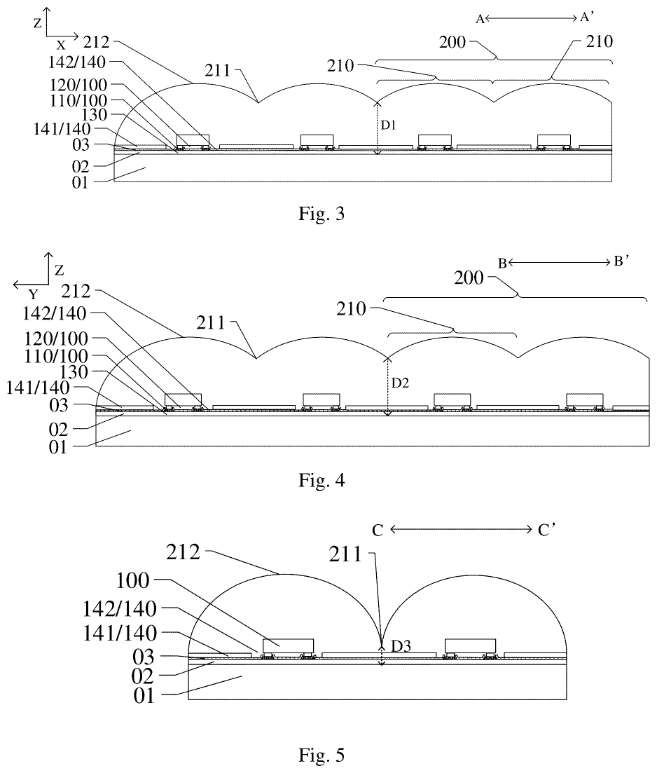

FIG. 2 is a schematic diagram of a planar structure of a light-emitting substrate according to an embodiment of the present disclosure. FIG. 3 is a schematic diagram of a partial cross-sectional structure cut along line AA′ shown in FIG. 2.

As shown in FIGS. 2 and 3, the light-emitting substrate includes a substrate 01 and a plurality of light-emitting units 100 and a light-transmission protective structure 20 that are located on the substrate 01. The substrate 01 includes a plurality of dimming partitions 10. The light-transmission protective structure 20 wraps the plurality of light-emitting units 100, except for portions in contact with the substrate 01. Each dimming partition 10 includes at least one light-emitting unit 100, the light-transmission protective structure 20 includes a plurality of sub-protective structure groups 200 disposed in one-to-one correspondence with the plurality of dimming partitions 10, each sub-protective structure group 200 wraps the light-emitting unit 100 in one dimming partition 10, and adjacent sub-protective structure groups 200 corresponding to at least two adjacent dimming partitions 10 are integrated. For example, the adjacent sub-protective structure groups 200 corresponding to at least two adjacent dimming partitions 10 are connected completely, without any gap therebetween. The dimming partition 10 in this embodiment may be the same partition as the dimming partition 010 shown in FIG. 1C.

FIG. 2 schematically shows six rows and six columns of light-emitting units 100. However, this embodiment is not limited thereto, the number of the light-emitting units 100 may be more. FIG. 2 schematically shows one dimming partition 10 including four light-emitting units 100. However, this embodiment is not limited thereto, one dimming partition 10 may include other numbers of light-emitting units 100, such as one light-emitting unit 100, two light-emitting units 100, an even number of light-emitting units 100, one row of light-emitting units 100, one column of light-emitting units 100, or n² light-emitting units 100.

In the light-emitting substrate provided in the present disclosure, each dimming partition 10 is correspondingly provided with one sub-protective structure group 200 wrapping the light-emitting unit 100 in the dimming partition 10, and adjacent sub-protective structure groups 200 corresponding to at least two adjacent dimming partitions 10 are integrated, so that the pitch of the light-emitting units 100 is not subject to the dimensional limitation of the light-transmission protective structure 20, such as without considering the overlap of the corresponding light-transmission protective structures 20 of the adjacent light-emitting units 100, to have a higher design freedom, and at the same time, the modulation of light emitted from each dimming partition 10 in all directions and the optimized control of the overall light pattern can be achieved, the matching with a Local Dimming algorithm can also be achieved, thereby making the light-emitting substrate have a better light uniformization effect.

For example, through the local dimming algorithm, the luminance of the light-emitting units 100 may be adjusted by partitioning, achieving effects such as weak halo, high screen uniformity, high contrast and high luminance. The sub-protective structure group 200 disposed in the dimming partition 10 covers the light-emitting units 100 within the dimming partition 10 as a whole to modulate the light emitted from each dimming partition in all directions so as to achieve the matching with the local dimming algorithm while achieving the optimized control of the overall light pattern, thus facilitating further improvement of the light uniformization effect of the light-emitting substrate.

For example, as shown in FIG. 2, this embodiment of the present disclosure is described as an example in which the same number of light-emitting units 100 are disposed in different dimming partitions 10. However, this embodiment is not limited thereto, different numbers of light-emitting units 100 may be provided for the dimming partitions 10 at different positions according to product conditions.

For example, as shown in FIG. 3, the substrate 01 may be a printed circuit board (PCB) or glass, plastic, polyimide, polymethylmethacrylate, etc., on which circuits are manufactured.

For example, as shown in FIG. 3, a buffer layer 02 (Buffer) is disposed on the substrate 01. For example, a pad 130 is disposed on a side of the buffer layer 02 away from the substrate 01, the light-emitting unit 100 includes a pin 110 and a light-emitting body 120, and the pin 110 of the light-emitting unit 100 is electrically connected to the pad 130. For example, a passivation layer 03 (PVX) is also disposed on the of the buffer layer 02 away from the substrate 01. For example, the passivation layer 03 is made of an insulating material, and the passivation layer 03 includes an opening at least exposing the pad 130 to enable an electric connection between the pin 110 of the light-emitting unit 100 and the pad 130 exposed from the passivation layer 03. The light-emitting unit 100 may be an upright light-emitting diode or an inverted light-emitting diode. FIG. 3 schematically shows only the buffer layer 02 and the passivation layer 03 between the light-emitting units 100 and the substrate 01. However, this embodiment is not limited thereto, other film layers may be included between the light-emitting units 100 and the substrate 01, for example, other film layers may be included between the buffer layer 02 and the passivation layer 03.

In some examples, as shown in FIG. 3, the light-emitting substrate further includes a reflection pattern 140. The reflection pattern 140 includes openings 142 and a reflection layer 141 surrounding the openings 142. The openings 142 are configured to expose the light-emitting units 100. In a direction perpendicular to the substrate 01, the reflection layer 141 overlaps the light-transmission protective structure 20 and is located between the light-transmission protective structure 20 and the substrate 01. For example, the reflection layer 141 is located on a side of the passivation layer 03 away from the substrate 01. For example, the light-transmission protective structure 20 covers the reflection layer 141. For example, the material of the reflection layer 141 includes white ink and/or silicone-based white glue. For example, the light-transmission protective structure 20 covers the edges of the openings 142.

For example, as shown in FIG. 3, the light-emitting diode may be a sub-millimeter light-emitting diode (Mini LED) or a micro light-emitting diode (Micro LED).

In some examples, as shown in FIG. 2, the light-emitting unit 100 includes an unpackaged light-emitting diode chip, and the maximum size of the unpackaged light-emitting diode chip in the direction parallel to the substrate 01 is not greater than 500 micrometers. For example, each light-emitting unit 100 may include a p-electrode, a p-type semiconductor layer, an n-electrode, an n-type semiconductor layer, and a light-emitting layer. Holes and electrons are injected into the n-type semiconductor layer and the p-type semiconductor layer from the n-electrode and the p-electrode, respectively, and recombine in the light-emitting layer, and manifesting the release of energy in the form of photons, where the light-emitting wavelength is dependent on a band gap of a luminescent material.

For example, as shown in FIG. 2, the maximum size of the light-emitting unit 100 in a direction parallel to the substrate 01 is not greater than 300 micrometers. For example, the maximum size of the light-emitting unit 100 in the direction parallel to the substrate 01 is not greater than 250 micrometers. For example, the maximum size of the light-emitting unit 100 in the direction parallel to the substrate 01 is not greater than 220 micrometers. For example, the maximum size of the light-emitting unit 100 in the direction parallel to the substrate 01 is not greater than 200 micrometers. For example, the maximum size of the light-emitting unit 100 in the direction parallel to the substrate 01 is not greater than 150 micrometers.

For example, as shown in FIG. 2, a contour of an orthographic projection of the light-emitting unit 100 on the substrate 01 may be in the shape of a rectangle, and the maximum size of the light-emitting unit 100 in the direction parallel to the substrate 01 may be a length of a diagonal of the light-emitting unit 100. Of course, this embodiment of the present disclosure is not limited thereto. For example, the contour of the orthographic projection of the light-emitting unit 100 on the substrate 01 may be circular, and the maximum size of the light-emitting unit 100 in the direction parallel to the substrate 01 may be a diameter of the light-emitting unit 100. For example, the contour of the orthographic projection of the light-emitting unit 100 on the substrate 01 may be oval, and the maximum size of the light-emitting unit 100 in the direction parallel to the substrate 01 may be a length of a long axis of the light-emitting unit 100. However, this embodiment is not limited thereto, a side length of the planar shape of the light-emitting unit 100 is also not greater than 500 micrometers.

For example, as shown in FIG. 3, the light-transmission protective structure 20 may wrap the portion of the light-emitting unit 100 other than the surface where the pin 110 and the pad 130 are connected electrically, to package and protect the unpackaged light-emitting unit 100. For example, the light-transmission protective structure 20 is in direct contact with the light-emitting unit 100, e.g., the surface of the light-emitting unit 100 away from the substrate 10 and the side surface of the light-emitting unit 100 are in direct contact with the light-transmission protective structure 20. For example, there may be no gap between the light-transmission protective structure 20 and the light-emitting unit 100 to avoid the reflection of light between the light-emitting unit 100 and the light-transmission protective structure 20. For example, the light-transmission protective structure 20 may be in contact with a portion of the surface of the reflection layer 141 away from the substrate 01. Of course, this embodiment of the present disclosure is not limited thereto, the side that is of the reflection layer 141 and that is away from the substrate 01 may also be provided with another film layer, and the light-transmission protective structure 20 may be in contact with a surface on a side that is of the other film layer and that is away from the substrate 01.

In some examples, as shown in FIGS. 2 and 3, the light-transmission protective structure 20 is made of a material of organosilicon, and the light-transmission protective structure 20 has a refractive index of 1.3-1.7 and a transmittance rate of greater than 80%. For example, the light-transmission protective structure 20 has a refractive index of 1.47-1.53. For example, the light-transmission protective structure 20 has a transmittance rate of greater than 90%. For example, the light-transmission protective structure 20 has a transmittance rate of greater than 95%. For example, the light-transmission protective structure 20 may be made of transparent silicone. For example, the light emitted from the light-emitting unit 100 is refracted by the light-transmission protective structure 20 and then emitted, and the shape of the light-transmission protective structure 20 may determine the secondary pattern of the light emitted from the light-emitting unit 100. In the light-emitting substrate provided in the present disclosure, the light-transmission protective structure 20 covering the light-emitting unit 100 may be used as a lens to optimize the light exit angle of the light-emitting unit 100. Because the organic silicone has a certain refractive index, e.g., a refractive index greater than the refractive index of the air, the light emitted from the light-emitting unit 100 is refracted when it is emitted from the organic silicone to the air or other media, so that the secondary pattern of the light emitted from the light-emitting unit 100 is changed when the light is emitted from the organic silicone.

In some examples, as shown in FIGS. 2 and 3, each sub-protective structure group 200 includes at least one sub-protective structure 210, the number of the sub-protective structures 210 is the same as the number of the plurality of light-emitting units 100, the sub-protective structures 210 and the plurality of light-emitting units are disposed in one-to-one correspondence, and at least some of the sub-protective structures 210 are integrated. For example, each dimming partition 10 includes a plurality of light-emitting units 100, each sub-protective structure group 200 includes a plurality of sub-protection structures 210, and at least some of the integrated sub-protective structures 210 described above may be the sub-protective structures 210 corresponding to the same dimming partition 10, or may be the sub-protective structures 210 corresponding to different dimming partitions 10. For example, the plurality of sub-protective structures 210 included in the same sub-protective structure group 200 may be of an integrated structure. For example, the sub-protective structures 210 included in different sub-protective structure groups 200 may be of an integrated structure. The above “integrated structure” may refer to that two sub-protective structures overlap spatially (not just overlap at the edge) to form a complete single structure. For example, they are made of the same material or are prepared in the same process.

In some examples, as shown in FIGS. 2 and 3, the sub-protective structures 210 provided corresponding to the same dimming partition 10 are integrated. For example, the sub-protective structures 210 included in the same sub-protective structure group 200 are of an integrated structure. For example, the plurality of sub-protective structures 210 included in the same sub-protective structure group 200 are connected completely, without any gap therebetween.

In the light-emitting substrate provided in the present disclosure, each dimming partition 10 includes a plurality of light-emitting units 100. By integrally setting multiple sub-protective structures 210 in the sub-protective structure group 200 corresponding to each dimming partition 10, not only can the overall design of multiple sub-protective structures 210 corresponding to a single dimming partition 10 be achieved to effectively modulate the patterns of light emitted from multiple light-emitting units 100 within the dimming partition 10 while matching the dynamic local dimming algorithm of the dimming partition 10, but also there is no need to consider the overlapping problem of adjacent sub-protective structures. The pitch of the light-emitting unit 100 can be designed to be smaller, thereby achieving a higher design freedom. The light-emitting substrate provided by the present disclosure can be implemented in Mini LED backlight products with higher partitions.

In some examples, as shown in FIGS. 2 and 3, a surface on a side that is of the integrated adjacent sub-protective structures 210 and that is away from the substrate 01 includes a concave portion 211 curving toward the light-emitting units 100, and the concave portion 211 is between the adjacent light-emitting units 100. For example, the concave portion 211 includes, on both sides in the X-direction or the Y-direction, convex portions 212 of the light-transmission protective structure that are farthest from the substrate 01. For example, the concave portion 211 may refer to a point in the surface on a side that is of the light-transmission protective structure 20 and that is away from the substrate 01. For example, the convex portion 212 may refer to a point in the surface on the side that is of the light-transmission protective structure 20 and that is away from the substrate 01, the point being farthest from the substrate 01.

For example, as shown in FIG. 3, the convex portions 212 and the concave portions 211 may be arranged alternately. For example, the convex portions 212 and the concave portions 211 may be arranged at equal spacing. For example, the convex portions 212 and the concave portions 211 may be spaced at equal spacing in the X-direction or the Y-direction. For example, the thickness of the sub-protective structure 210 at the concave portion 211 (e.g., the size of the sub-protective structure 210 in a Z-direction perpendicular to the substrate 01) is less than its thickness at the convex portion 212.

For example, as shown in FIG. 3, each sub-protective structure 210 includes one convex portion 212, and the adjacent sub-protective structures 210 are connected as a whole at the concave portion 211. For example, the ratio of distances between the convex portions 212 in different sub-protective structures 210 and the substrate 01 may be 0.9-1.1. For example, the distances between the convex portions 212 in the different sub-protective structures 210 and the substrate 01 may be equal. For example, the distances between the different concave portions 211 and the substrate 01 may be the same or different. For example, the distances between the concave portions 211 arranged in the same direction, e.g., the X-direction or the Y-direction, and the substrate 01 may be the same, and the distances between the concave portions 211 arranged in different directions and the substrate 01 may be different.

For example, as shown in FIG. 3, in the direction perpendicular to the substrate 01, such as the Z-direction, the convex portion 212 overlaps the light-emitting unit 100. For example, in the direction perpendicular to the substrate 01, the concave portion 211 overlaps the reflection layer 141.

In some examples, as shown in FIG. 3, a surface of the sub-protective structure 210 away from the substrate 01 has a point, e.g., the position of the convex portion 212, with the greatest distance from the substrate 01, a distance between an orthographic projection of the point on the substrate and a center of an orthographic projection, on the substrate 01, of the light-emitting unit 100 covered with the sub-protective structure 210 is not greater than 2% of the maximum size of the orthographic projection of the light-emitting unit 100. For example, a distance between an orthographic projection, on the substrate 01, of the sub-protective structure 210 at the convex portion 212 and the center of the orthographic projection, on the substrate 01, of the light-emitting unit 100 covered with the sub-protective structure 210 is not greater than 1% of the maximum size of the orthographic projection of the light-emitting unit 100. For example, the orthographic projection, on the substrate 01, of the convex portion 212 coincides with the center of the orthographic projection, on the substrate 01, of the light-emitting unit 100. For example, a straight line passing through the convex portion 212 and perpendicular to the substrate 01 passes through a geometric center of the body of the light-emitting unit 100. For example, an orthographic projection, on the substrate 01, of the concave portion 211 coincides with the center of the spacing between the light-emitting units 100. For example, the convex portion does not overlap with the pin 110 of the light-emitting unit 100 in the direction perpendicular to the substrate 01.

In some examples, as shown in FIGS. 2 and 3, the plurality of light-emitting units 100 is arranged in an array along the first direction and the second direction. The first direction intersects the second direction, e.g., the first direction is perpendicular to the second direction, the first direction may be the X-direction, and the second direction may be the Y-direction. However, this embodiment is not limited thereto, the first direction and the second direction may be interchanged. The spacing of the plurality of light-emitting units 100 in the first direction is equal to the spacing of the plurality of light-emitting units 100 in the second direction, and the plurality of sub-protective structures 210 are of an integrated structure.

In the light-emitting substrate provided in the present disclosure, the light-transmission protective structure 20 that protects all the light-emitting units 100 is disposed as an integrated structure, to carry out an overall light uniformization design of the light-emitting substrate, which is conducive to realizing a high image-display quality.

For example, as shown in FIGS. 2 and 3, the plurality of convex portions 212 included in the plurality of sub-protective structures 210 is arranged in an array along the first direction and the second direction and is arranged at equal spacing in the first direction and the second direction. For example, the concave portions 211 are arranged at equal spacing in the first direction and the concave portions 211 are arranged at equal spacing in the second direction.

In some examples, as shown in FIG. 3, a surface of the light-transmission protective structure 20 that covers the plurality of light-emitting units 100 includes a free-form surface. For example, the surface on a side that is of each sub-protective structure 210 and that is away from the substrate 01 may be a spherical surface. For example, surfaces on the sides that are of at least some of the sub-protective structures 210 and that are away from the substrate 01 may have the same type. For example, the areas of the surfaces on the sides that are of the different sub-protective structures 210 and that are away from the substrate 01 may be the same or different. For example, the areas of the surfaces on the sides that are of some of the sub-protective structures 210 and that are away from the side of the substrate 01 may be the same.

In some examples, as shown in FIG. 2, the contour of the orthographic projection, on the substrate 01, of the light-transmission protective structure 20 includes a plurality of curved segments 220 connected in sequence, each curved segment 220 curves to a side away from the center of the orthographic protection of the light-transmission protective structure 20, and a distance between at least one endpoint of the curved segment 220 and the center of the orthographic protection of the light-transmission protective structure 20 is less than a distance between another point of the curved segment 220 and the center of the orthographic protection of the light-transmission protective structure 20. For example, the light-transmission protective structure 20 is of an integrated structure, and the contour of the orthographic projection, on the substrate 01, of the light-transmission protective structure 20 is composed of a plurality of curved segments 220 that are connected end to end. For example, different curved segments 220 may have the same or different shapes. For example, a connection point of adjacent curved segments 220 may be located between adjacent light-emitting units 100, e.g., may correspond to a midpoint of a centerline of the adjacent light-emitting units 100.

In some examples, as shown in FIG. 2, the plurality of light-emitting units 100 includes peripheral light-emitting units 101 closest to the contour of the orthographic projection, on the substrate 01, of the light-transmission protective structure 20, and the number of the plurality of curved segments 220 may be the same as the number of peripheral light-emitting units 101. For example, the number of the plurality of curved segments 220 may be the same as the number of the peripheral light-emitting units 101 described above.

For example, as shown in FIG. 2, the plurality of light-emitting units 100 includes a circle of light-emitting units 101 located at the outermost periphery, which are close to the curved segments 220 of the light-transmission protective structure 20. For example, the light-emitting units 101 at the outermost periphery surround other light-emitting units 102. For example, some of the light-emitting units 100 within a certain dimming partition 10 are peripheral light-emitting units 101. For example, all of the light-emitting units 100 within a certain dimming partition 10 are peripheral light-emitting units 101. For example, the light-emitting units 100 within a certain dimming partition 10 do not include peripheral light-emitting units 101.

For example, as shown in FIG. 2, the plurality of curved segments 220 may be disposed in one-to-one correspondence with the peripheral light-emitting units 101. For example, a line connecting the midpoint of each of some curved segments 220 with the geometric center of its corresponding light-emitting unit 100 may be substantially parallel to the first direction or the second direction. For example, the curved segments 220 include a plurality of first curved segments 221 and a plurality of second curved segments 222. The plurality of second curved segments 222 include two parts of second curved segments 222 arranged in the X-direction and connected end to end, and two other parts of second curved segments 222 arranged in the Y-direction and connected end to end. The plurality of first curved segments 221 may include four first curved segments 221. Each of the first curved segments 221 includes a first end and a second end. The first end of each first curved segment 221 is connected to one end of the second curved segment 222 arranged in the X-direction and located at the most edge, and the second end of each first curved segment 221 is connected to one end of the second curved segment 222 arranged in the Y-direction and located at the most edge, e.g., each first curved segment 221 is used for connecting the two second curved segments 222 that are arranged in the X-direction and the Y-direction, respectively and have the closest distance from each other. For example, a plurality of second curved segments 222 connected in sequence are provided between two first curved segments 221 arranged in the first direction, and a plurality of second curved segments 222 connected in sequence are provided between two first curved segments 221 arranged in the second direction. For example, two endpoints of each first curved segment 221 are connected to two second curved segments 222, respectively; and two endpoints of each of some second curved segments 222 are connected to the second curved segments 222, respectively. For example, the length of the first curved segment 221 is greater than the length of the second curved segment 222. For example, the ratio of lengths of the different first curved segments 221 is 0.95-1.01, e.g., 1. For example, the ratio of lengths of the different second curved segments 222 is 0.95-1.01, e.g., 1.

In some examples, as shown in FIG. 2, the curved segments 220 include arc segments, and the central angle corresponding to the arc segments is not greater than 280 degrees. For example, the central angle of the first curved segment 221 is greater than that of the second curved segment 222. For example, the central angle of the first curved segment 221 is not greater than 250 degrees, such as not greater than 220 degrees, such as not greater than 180 degrees, such as greater than 90 degrees, such as greater than 100 degrees, such as greater than 110 degrees, and such as greater than 120 degrees. For example, the central angle of the second curved segment 222 is not greater than 180 degrees, such as not greater than 160 degrees, such as not greater than 150 degrees, such as not greater than 130 degrees, such as not greater than 120 degrees, such as not greater than 110 degrees, such as not greater than 100 degrees, such as not greater than 90 degrees, such as not greater than 80 degrees, and such as not greater than 70 degrees, such as greater than 5 degrees, such as greater than 10 degrees, such as greater than 15 degrees, such as greater than 20 degrees, such as greater than 25 degrees, such as greater than 30 degrees, such as greater than 45 degrees, and such as greater than 60 degrees.

For example, as shown in FIG. 2, the ratio of the central angles of different first curved segments 221 is 0.95-1.01, such as 1. For example, the ratio of the central angles of different second curved segments 222 is 0.95-1.01, such as 1.

In some examples, as shown in FIG. 2, the plurality of light-emitting units 100 is arranged in an array along the first direction and the second direction, the first direction is perpendicular to the second direction. For example, the first direction may be the X-direction and the second direction may be the Y-direction, but this embodiment is not limited thereto, the first direction and the second direction may be interchangeable.

FIG. 4 is a schematic diagram of a partial cross-sectional structure cut along line BB′ shown in FIG. 2. FIG. 5 is a schematic diagram of a partial cross-sectional structure cut along line CC′ shown in FIG. 2.

In some examples, as shown in FIGS. 2 to 4, the minimum distance between the concave portion 211 provided between adjacent light-emitting units 100 arranged in the first direction and the substrate 01 is a first distance D1, the minimum distance between the concave portion 211 provided between adjacent light-emitting units 100 arranged in the second direction and the substrate 01 is a second distance D2, and the ratio of the first distance to the second distance is 0.95-1.05. For example, the first distance and the second distance are equal. For example, the minimum distance between the concave portion 211 provided between adjacent light-emitting units 100 arranged in the first direction and the reflection layer 141 is a first sub-distance, the minimum distance between the concave portion 211 provided between adjacent light-emitting units 100 arranged in the second direction and the reflection layer 141 is a second sub-distance, and the ratio of the first sub-distance to the second sub-distance is 0.95-1.05. For example, the first sub-distance and the second sub-distance are equal.

In some examples, as shown in FIG. 2, the plurality of light-emitting units 100 includes adjacent light-emitting units 100 arranged in a third direction. Both the first direction and the second direction intersect the third direction. For example, the angle between the third direction and the first direction may be 30-60 degrees, such as 45 degrees.

In some examples, as shown in FIGS. 2 to 5, the minimum distance between the concave portion 211 provided between adjacent light-emitting units 100 arranged in the third direction and the substrate 01 is a third distance D3, and the first distance D1 is greater than the third distance D3. For example, the second distance is greater than the third distance. For example, the minimum distance between the concave portion 211 provided between the adjacent light-emitting units 100 arranged in the third direction and the reflection layer 141 is a third sub-distance, for example, the third sub-distance is close to zero.

For example, as shown in FIGS. 2 to 4, the distance between adjacent light-emitting units 100 arranged in the third direction is greater than the distance between adjacent light-emitting units 100 arranged in the first direction, and the distance between the concave portion 211, between adjacent light-emitting units 100 arranged in the third direction, and the substrate 01 is less than the distance between the concave portion 211, between adjacent light-emitting units 100 arranged in the first direction, and the substrate 01. For example, the greater the distance between adjacent light-emitting units 100, the smaller the distance between the concave portion 211 between these adjacent light-emitting units 100 and the substrate 01. For example, the distances between adjacent light-emitting units 100 arranged in different directions are different, and the distances between the concave portion 211 located between adjacent light-emitting units 100 arranged in different directions and the substrate 01 are different. For example, the concave portion 211 may be in contact with a layer closest to the light-transmission protective structure 20, such as the reflection layer 141.

In some examples, as shown in FIG. 2, the curved segment 220 is an arc segment, the radius of a circle in which the arc segment is located is r, the distance between centers of adjacent light-emitting units 100 is L, and L and r satisfy the relation equation: L/2≤r≤L.

The distance between the centers of adjacent light-emitting units 100 is approximately equal to the distance between adjacent light-emitting units 100 when the dimension of the light-emitting unit 100 differs significantly from the dimension of the sub-protective structure 210, for example, as described herein. In the case where the dimension of the light-emitting unit 100 is taken into account, such as the dimension of the light-emitting unit 100 in an arrangement direction of these adjacent light-emitting units 100 is a, then L, a, and r satisfy the relation equation: L/2≤r≤(L−a/2).

The curved segment 220 of the contour edge of the light-transmission protective structure 20 is set as an arc segment, and the relationship between the radius of the circle where the arc segment is located and the distance between the light-emitting units 100 is defined, so it is possible to realize the integration of the sub-protective structures 210 corresponding to the adjacent light-emitting units 100 in an arbitrary direction while preventing the sub-protective structure 210 from covering the light-emitting units 100 other than the light-emitting units 100 provided corresponding thereto to affect the light pattern thereof.

For example, as shown in FIG. 2, the distance L between the centers of the adjacent light-emitting units 100 described above may be a pitch of the adjacent light-emitting units 100. For example, L and r satisfy the relation equation: 0.6*L≤r≤0.9*L. For example, L and r satisfy the relation equation: 0.7*L≤r≤0.8*L. For example, the distance between adjacent light-emitting units 100 arranged in different directions may be the same, both being L. FIG. 2 schematically shows that L may be a distance between the centers of two adjacent light-emitting units 100 arranged in the first direction. However, this embodiment is not limited thereto, L may also be a distance between the centers of two adjacent light-emitting units 100 arranged in the second direction, or a distance between the centers of two adjacent light-emitting units 100 arranged in the third direction.

For example, as shown in FIGS. 2 and 3, the orthographic projection, on the substrate 01, of each sub-protective structure 210 is located in a circular region, the orthographic projection, on the substrate 01, of the center of the surface on the side that is of the sub-protective structure 210 and that is away from the substrate 01 substantially coincides with the center of the circular region, and the radius of the circular region is the radius r of the circle in which the arc segment described above is located. For example, the center of the orthographic projection of the light-emitting unit 100 on the substrate 01 substantially coincides with the center of the circular region. The substantial coincidence means that the ratio of the distance between the two points to the radius r is not greater than 0.05, taking into account the process deviation, for example, it is not greater than 0.02, and the distance between the two points is infinitely close to zero.

For example, as shown in FIG. 2, the respective curved segments 220 of the light-transmission protective structure 20 are arc segments, and the radii of the circles in which the arc segments are located are substantially equal. The above substantially equal means that the ratio of the radii of the circles in which the different arc segments are located is 0.95-1.05, with the ratio being infinitely close to 1, taking into account the process deviation.

In some examples, as shown in FIG. 2, the pitch of the light-emitting units 100 arranged along the first direction is a first pitch p1, the pitch of the light-emitting units 100 arranged in the second direction is a second pitch p2, the first pitch is not less than the second pitch, and pl and r satisfy the relation equation: {[(p1)²+(p2)²]^{1/2}}/2≤r≤p1.

Described herein as an example, the pitch of the adjacent light-emitting units 100 is approximately equal to the distance between the adjacent light-emitting units 100 when the dimension of the light-emitting unit 100 differs significantly from the dimension of the sub-protective structure 210. Considering the dimension of the light-emitting units 100, for example, in the case where the dimension of the light-emitting unit 100 in the first direction is a and the dimension thereof in the second direction is b, then p1, p2, a, b, and r satisfy the relation equation: {[(p1)²+(p2)²]^{1/2}}/2≤r≤(p1−a/2).

The curved segment 220 of the contour edge of the light-transmission protective structure 20 is set as an arc segment, and the relationship between the radius of the circle where the arc segment is located and the distance between the light-emitting units 100 is defined, so it is possible to realize the integration of the sub-protective structure 210 corresponding to the adjacent light-emitting units 100 in an arbitrary direction while preventing the sub-protective structure 210 from covering the light-emitting units 100 other than the light-emitting units 100 provided corresponding thereto to affect the light pattern thereof.

For example, as shown in FIG. 2, when the first pitch and the second pitch are equal and both are p, p and r satisfy the relation equation: 2^{1/2}*p/2≤r≤p. For example, the plurality of light-emitting units 100 are arranged at equal spacing in both the first direction and the second direction.

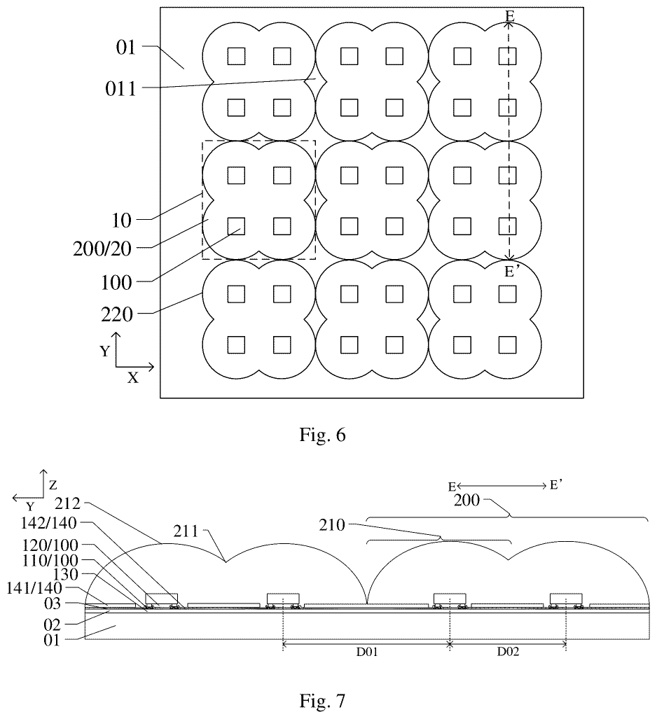

FIG. 6 is a schematic diagram of a partial planar structure of a light-emitting substrate according to another example of an embodiment of the present disclosure. FIG. 7 is a schematic diagram of a partial cross-sectional structure cut along line EE′ shown in FIG. 6. The light-emitting substrate shown in FIG. 6 differs from the light-emitting substrate shown in FIG. 2 in that the light-transmission protective structures 20 are different.

In some examples, as shown in FIGS. 6 and 7, in at least some of the dimming partitions 10, there is a gap 011 between adjacent sub-protective structure groups 200 corresponding to adjacent dimming partitions 10, and a surface on a side that is of the same sub-protective structure group 200 and that is away from the substrate 01 includes a concave portion 211 that curves toward a side close to the light-emitting unit 100, and the concave portion 211 is located between the adjacent light-emitting units 100. FIG. 6 schematically shows one dimming partition 10 including four light-emitting units 100. However, this embodiment is not limited thereto, the number of light-emitting units 100 in the dimming partition 10 may be set according to need.

For example, as shown in FIGS. 6 and 7, each sub-protective structure group 200 includes at least one sub-protective structure 210, the number of sub-protective structures 210 is the same as the number of the plurality of light-emitting units 100, the sub-protective structures 210 and the plurality of light-emitting units 100 are disposed in one-to-one correspondence, and the plurality of sub-protective structures 210 corresponding to the same dimming partition 10 are integrated.

For example, as shown in FIGS. 6 and 7, adjacent sub-protective structure groups 200 in some regions may be of an integrated structure, while there is a gap 011 between adjacent sub-protective structure groups in some other regions. Of course, this embodiment of the present disclosure is not limited thereto, and the adjacent sub-protective structure groups 200 are spaced apart completely. FIG. 6 schematically shows that there are gaps between the adjacent sub-protective structure groups arranged in the X-direction and the adjacent sub-protective structure groups arranged in the Y-direction, respectively. However, this embodiment of the present disclosure is not limited thereto. There may be a gap between the adjacent sub-protective structure groups arranged in one of the X-direction and the Y-direction, and there may be no gap at all between the adjacent sub-protective structure groups arranged in the other of the X-direction and the Y-direction, for example, the adjacent sub-protective structure groups are connected to each other as an integrated structure at respective positions.

For example, as shown in FIGS. 6 and 7, the plurality of light-emitting units 100 located in the same dimming partition 10 may be uniformly distributed and the plurality of dimming partitions 10 are uniformly distributed. For example, a distance D02 between adjacent light-emitting units 100 in the same dimming partition 10 is less than a distance D01 between adjacent light-emitting units 100 in different dimming partitions 10. For example, the distance between adjacent light-emitting units 100 arranged in the X-direction and the distance between adjacent light-emitting units 100 arranged in the Y-direction within the same dimming partition 10 may be the same. For example, the distance between two adjacent light-emitting units 100 that are respectively located in two adjacent dimming partitions 10 arranged in the X-direction may be the same as or different from the distance between two adjacent light-emitting units 100 that are respectively located in two adjacent dimming partitions 10 arranged in the Y-direction.

For example, as shown in FIGS. 6 and 7, the dimension, in the first direction, of the gap 011 between the adjacent sub-protective structure groups 200 arranged in the first direction may be the same as the dimension, in the second direction, of the gap 011 between the adjacent sub-protective structure groups 200 arranged in the second direction. For example, the dimension, in the third direction, of the gap 011 between the adjacent sub-protective structure groups 200 arranged in the third direction is larger than the dimension, in the first direction, of the gap 011 between the adjacent sub-protective structure groups 200 arranged in the first direction.

For example, as shown in FIGS. 6 and 7, a surface on a side of the sub-protective structure 210 away from the substrate 01 has a point, e.g., the position of the convex portion 212, with the greatest distance from the substrate 01, the distance between an orthographic projection of the point on the substrate 01 and the center of an orthographic projection, on the substrate 01, of the light-emitting unit 100 covered with the sub-protective structure 210 is not greater than 2% of the maximum size of the orthographic projection of the light-emitting unit 100. For example, the orthographic projection, on the substrate 01, of the convex portion 212 coincides with the center of the orthographic projection, on the substrate 01, of the light-emitting unit 100.

For example, as shown in FIGS. 6 and 7, in some regions, the shape and area of the orthographic projections, on the substrate 01, of different sub-protective structure groups 200 may all be the same. For example, the light-emitting substrate includes different regions, the shapes of the sub-protective structure groups 200 in different regions, respectively, may be different. For example, the distances between the concave portions 211 and the substrate 01 in different sub-protective structure groups 200 may be substantially equal.

For example, as shown in FIG. 6, the contour of the orthographic projection, on the substrate 01, of each sub-protective structure group 200 includes a plurality of curved segments 220 connected in sequence, each curved segment 220 curves to a side away from the center of the orthographic protection of the sub-protective structure group 200, and a distance between at least one endpoint of the curved segment 220 and the center of the orthographic protection of the sub-protective structure group 200 is less than a distance between another point of the curved segment 220 and the center of the orthographic protection of the sub-protective structure group 200. For example, different curved segments 220 may have the same or different lengths.

For example, as shown in FIG. 6, the curved segment 220 includes an arc segment, and the central angle corresponding to the arc segments is not greater than 280 degrees. For example, the radius of a circle in which the arc segment is located is r, the distance between centers of adjacent light-emitting units 100 is L, and L and r satisfy the relation equation: L/2≤r≤L. For example, the plurality of light-emitting units 100 within the same dimming partition 10 is arranged in an array along a first direction X and a second direction Y, a pitch of the light-emitting units 100 arranged in the first direction is a first pitch p1, a pitch of the light-emitting units 100 arranged in the second direction is a second pitch p2, the first pitch is not less than the second pitch, and p1 and r satisfy the relation equation: {[(p1)²+(p2)²]^{1/2}}2≤r≤p1. In this example, the relationship between r and L and the relationship between r and p1 and p2 may be referred to the corresponding relationship in the display substrate in the above example.

In the light-emitting substrate provided in this example, the sub-protective structure group 200 corresponding to each dimming partition 10 is provided separately, and the gap 011 is provided between adjacent sub-protective structure groups 200, which is conducive to individually and flexibly adjusting the light pattern of light emitted from different dimming partitions 10. For example, the shape of the sub-protective structure group 200 corresponding to the dimming partition 10 at different positions may be specially set according to the light-emitting demand.

In the light-emitting substrate provided in the present disclosure, each dimming partition 10 includes a plurality of light-emitting units 100. The plurality of sub-protective structures 210 in the sub-protective structure group 200 corresponding to each dimming partition 10 are integrated, so that the overall design of the plurality of sub-protective structures 210 corresponding to a single dimming partition 10 can be realized to effectively modulate the light pattern of light emitted from the plurality of light-emitting units 100 in the dimming partition 10 while matching the dynamic local dimming algorithm of the dimming partition 10.

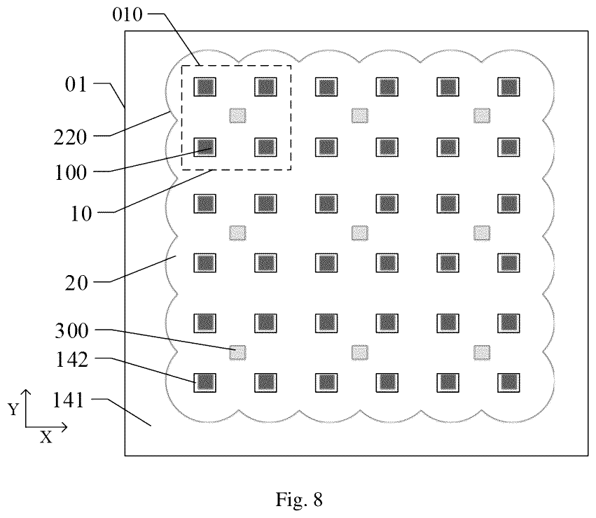

FIG. 8 is a schematic diagram of a planar structure of a light-emitting substrate according to another example of an embodiment of the present disclosure.

In some examples, as shown in FIG. 8, the light-emitting substrate further includes a driver chip 300 (IC) configured to control at least one dimming partition 10. A packaging structure is disposed between the driver chip 300 and the light-transmission protective structure 20. Specifically, the packaging structure may be used for preventing the driver chip 300 from falling off due to scraping in the manufacturing process, and the surface of the packaging structure may be made of a reflective material (e.g., white ink and/or silicone-based white glue), enabling an increase in the utilization rate of emergent light rays from the surrounding light-emitting units 10. The shape of the orthographic projection of the packaging structure may be circular, elliptical, polygonal, and other shapes, or may be similar to the shape of the orthographic projection of the driver chip 300, as long as the packaging structure can cover the driver chip 300.

FIG. 8 schematically shows that each drive partition is provided with one driver chip 300 therein such that each driver chip 300 is configured to control the luminance of the light-emitting units 100 within one dimming partition. However, this embodiment of the present disclosure is not limited thereto, and it is also possible that one driver chip 300 is configured to control the luminance of the light-emitting units 100 within at least two dimming partitions.

For example, FIG. 8 schematically shows the driver chip 300 being located close to the center of each dimming partition 10. However, this embodiment is not limited thereto, the driver chip 300 may also be moved upwardly between two adjacent light-emitting units 100 or downwardly, leftwardly, or rightwardly between two adjacent light-emitting units 100 as long as the light-emitting units 100 do not interfere with each other. In order to ensure the light-emitting efficiency of the light-emitting units 100, the driver chip 300 will be provided with the packaging structure, for example, a side of the driver chip 300 that is away from the substrate 01 is covered with a white silicone material and accordingly, the overall light-emitting efficiency of the light-emitting substrate will not be affected by specific position of the driver chip 300. Generally, for one dimming partition 10, its geometric center corresponds to the position with a higher luminance. In the embodiment of the present disclosure, the thickness of the light-transmission protective structure 20 in the center region of the dimming partition 10 is relatively small, and the driver chip 300 can be avoided as much as possible to be disposed in the center region of the dimming partition 10.

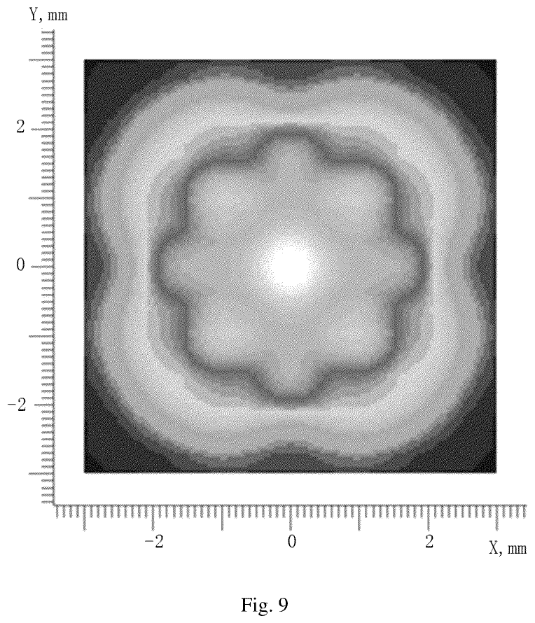

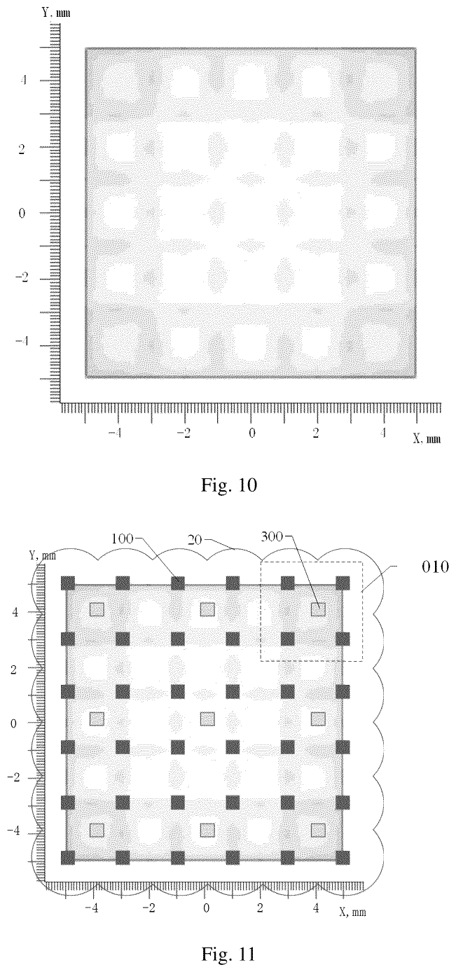

FIG. 9 is a luminance distribution diagram of one dimming partition 10 shown in FIG. 8. FIG. 10 is a luminance distribution diagram of a plurality of dimming partitions 10 shown in FIG. 8. FIG. 11 is a superimposed view of the plurality of dimming partitions shown in FIG. 8 and the luminance distribution diagram, shown in FIG. 10, corresponding to the dimming partitions 10. The horizontal coordinate X and the vertical coordinate Y in the respective luminance distribution diagrams indicate the size of a region detected by the detector.

For example, as shown in FIG. 1B and FIG. 9, as compared with a light-emitting substrate in which each light-emitting unit 100 in each dimming partition 10 is generally provided with a separate lens and the lenses cannot overlap, the light-emitting substrate provided in the present disclosure has the greatest luminance at the center point in response to the sub-protective structures 210 in each dimming partition 10 being integrated, and has a larger area of uniform distribution of luminance for the region outside of the center point, whereby the optical effect of the dimming partition provided in the present application is better. Similarly, as shown in FIG. 1D and FIG. 10, in the process of detecting the plurality of dimming partitions 10, the luminance uniformity of the light-emitting substrate provided in the present disclosure is significantly improved as compared to that of the structure shown in FIG. 1C.

FIG. 1E is a superimposed view of the plurality of dimming partitions shown in FIG. 1C and the luminance distribution diagram, shown in FIG. 1D, corresponding to the dimming partitions shown in FIG. 1C. FIG. 1E schematically shows a position corresponding relationship between the light and dark regions and the light-emitting units and the driver chips.

For example, as shown in FIG. 1E, in the center region of the light-emitting substrate, the position where the light-emitting unit 011 is located is bright, and a region between adjacent light-emitting units 011 is dark; and the luminance differentiation between the center region and an edge region of the light-emitting substrate is great. For example, as shown in FIG. 1E, the position of the light-emitting unit 100 located in the centermost region of the light-emitting substrate is the brightest, the light-emitting unit 100 located in the non-edge position is secondarily bright, and the light-emitting units 100 located at the four edges are the darkest. As a result, the light-emitting substrate of the design in which a single light-emitting unit is covered with a corresponding first encapsulation portion has very obvious bright and dark areas, and has poor luminance uniformity.

FIG. 11 is a superimposed view of the plurality of dimming partitions shown in FIG. 8 and the luminance distribution diagram, shown in FIG. 10, corresponding to the dimming partitions shown in FIG. 8. FIG. 11 schematically shows a positional relationship between a bright-spot region and the light-emitting units 100.

For example, as shown in FIG. 11, in the light-emitting substrate provided in the embodiment of the present disclosure, the luminance of either the position of the light-emitting unit 100 or a region between adjacent light-emitting units 100 is higher, and the differentiation of the luminance between the center region and the edge region of the light-emitting substrate is smaller. As a result, compared to the luminance distribution diagram shown in FIG. 1E, the luminance uniformity of the light-emitting substrate provided in the embodiment of the present disclosure can be significantly improved by covering all the light-emitting units in at least one dimming partition with the light-transmission protective structure.

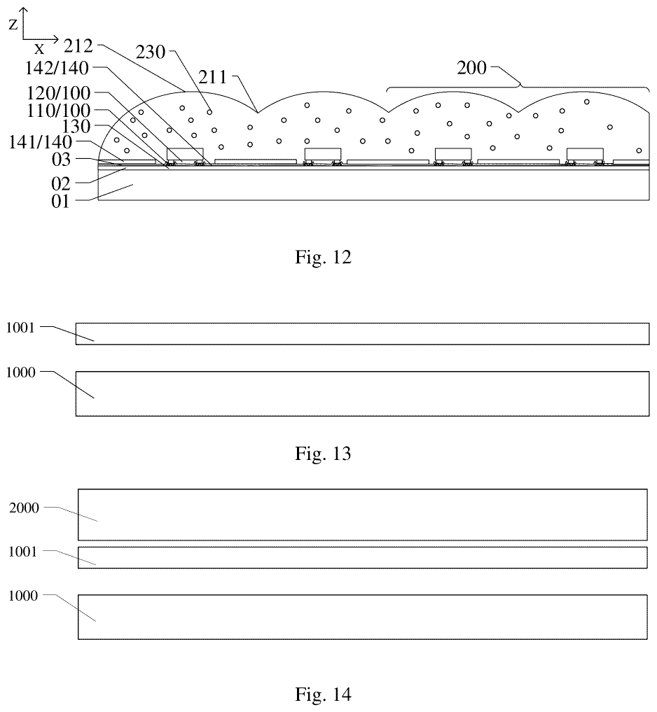

FIG. 12 is a partial cross-sectional view of a light-emitting substrate according to another example of an embodiment of the present disclosure.

In some examples, as shown in FIG. 12, the light-emitting unit 100 emits light at a wavelength of 430-480 nanometers and the light-transmission protective structure 20 includes an inorganic luminescent material 230. For example, the light-emitting unit 100 includes a blue light-emitting chip to emit blue light. For example, the light-emitting unit 100 may emit light at a wavelength of 440-460 nanometers, or 450-470 nanometers.

For example, the inorganic luminescent material 230 may be uniformly dispersed in the light-transmission protective structure 20, or gathered on the light exit side of the light-transmission protective structure 20.

For example, as shown in FIG. 12, the inorganic luminescent material 230 may include a fluorescent material. The fluorescent material may be inorganic particles, organic particles, or organic molecules or a combination thereof. Suitable inorganic particles include doped garnets (e.g., YAG:Ce, and (Y,Gd)AG:Ce), aluminates (e.g., Sr2A114O25:Eu, and BAM:Eu), silicates (e.g., SrBaSiO:Eu), sulphides (e.g., ZnS:Ag, CaS:Eu, and SrGa2S4:Eu), oxysulfides, oxo-nitrides, phosphates, borates, and tungstates (e.g., CaWO4). These materials may be in the form of powder of a conventional inorganic luminescent material 230 or powder of a nanoparticle inorganic luminescent material 230. Another suitable type of inorganic particles refers to the so-called quantum-dot inorganic luminescent material 230 made from semiconductor nanoparticles, including: silicon (Si), germanium (Ge), cadmium sulfide (CdS), cadmium selenide (CdSe), cadmium telluride (CdTe), zinc sulfide (ZnS), zinc selenide (ZnSe), zinc telluride (ZnTe), lead sulfide (PbS), lead selenide (PbSe), lead telluride (PbTe), indium nitride (InN), indium phosphide (InP), indium arsenide (InAs), aluminum nitride (AlN), aluminum phosphide (AlP), aluminum arsenide (AlAs), gallium nitride (GaN), gallium phosphide (GaP), gallium arsenide (GaAs), and combinations thereof. Generally, the surface of each quantum dot is at least partially covered with organic molecules, thereby preventing agglomeration and improving the compatibility with binders. In some cases, the semiconductor quantum dots may consist of several layers of different materials within a core-shell structure. Suitable organic molecules include fluorescent dyes. A phosphor layer may include a mixture of different types of inorganic luminescent materials 230 in a single layer or multiple layers, and each layer contains one or more inorganic luminescent materials 230. Particles of the inorganic luminescent material 230 in the phosphor layer may have different particle sizes (e.g., diameters) and may be separated.

This embodiment of the present disclosure is not limited thereto, and the light-emitting unit 100 may further include a red light-emitting chip and a green light-emitting chip, while the light-transmission protective structure 20 may not be provided with the inorganic luminescent material 230.

The light-transmission protective structure 20 provided in this embodiment of the present disclosure may be produced by various processes, such as any one of photolithography, printing, spraying, transfer printing, embossing, compression molding, and coating.

FIG. 13 is a schematic diagram of a partial cross-sectional structure of a backlight source according to another embodiment of the present disclosure. As shown in FIG. 13, the backlight source includes the light-emitting substrate 1000 in any of the above examples.

For example, as shown in FIG. 13, the backlight source further includes a light diffusion structure 1001 on the light exit side of the light-emitting substrate 1000. For example, the light diffusion structure 1001 may include at least one light diffusion layer. For example, the light diffusion structure 1001 may include a first light diffusion layer and a second light diffusion layer, one of the first light diffusion layer and the second light diffusion layer may be a particulate diffusion plate, and the other of the first light diffusion layer and the second light diffusion layer may be a diffusion film with microstructures on the surface. However, this embodiment is not limited thereto, for example, the light diffusion structure may include more diffusion layers.

For example, the backlight source may further include film layers such as a diffusion layer, a luminance enhancement film, a color conversion layer (not shown). For example, film layers such as the diffusion layer, the luminance enhancement film, the color conversion layer are all located on a side of the light diffusion structure away from the light-emitting substrate. For example, the luminance enhancement film may be a prism layer, which plays the role of concentrating light to improve the luminance in the front view. For example, the color conversion layer may convert light emitted from the light-emitting unit 100 from one color to another color. For example, when the light-emitting unit 100 emits blue light, the color conversion layer may include a phosphor layer that converts the blue light to white light. For example, the phosphor layer includes quantum dots that convert the blue light to red light and green light. For example, in addition to the phosphor layer, the color conversion layer may include part of the reflection structure. For example, the part of reflection structure (which may also be referred to as a dichroic structure or a dichroic filtering structure) may reflect all of the red and green light and reflect the blue light partially. When the backlight source is provided with a color conversion layer, the light-transmission protective structure 20 may not be provided with the inorganic luminescent material 230 shown in FIG. 12. For example, when the light-transmission protective structure 20 is provided with the inorganic luminescent material 230 shown in FIG. 12, the backlight source may not be provided with the color conversion layer.

FIG. 14 is a schematic diagram of a partial cross-sectional structure of a display apparatus according to another embodiment of the present disclosure. As shown in FIG. 14, the display apparatus includes the light-emitting substrate 1000 in any of the above examples. For example, as shown in FIG. 14, the display apparatus includes the backlight source shown in FIG. 13.

For example, as shown in FIG. 14, the display apparatus further includes a display panel 2000 stacked on the light-emitting substrate 1000. For example, the display panel 2000 is on the light exit side of the light-emitting substrate, and the light-emitting substrate is configured to provide back light to the display panel 2000. For example, the display panel 2000 may be a liquid crystal display panel. The liquid crystal display panel may include an array substrate (not shown), an opposing substrate (not shown), and a liquid crystal layer (not shown) located between the array substrate and the opposing substrate.

For example, one side of the array substrate facing toward the opposing substrate may include a plurality of gate lines extending in one direction and a plurality of data lines extending in another direction. The plurality of gate lines and the plurality of data lines intersect to define a plurality of pixel units in an array arrangement. The plurality of pixel units may be arranged as a pixel array. Each pixel unit may include a pixel electrode and a thin-film transistor. The gate line is connected to a gate of the thin-film transistor to turn on or off of the thin-film transistor. The pixel electrode is connected to one of the source electrode and the drain electrode of the thin-film transistor. The data line is connected to the other of the source electrode and the drain electrode of the thin-film transistor. The data lines input required voltage signals to the pixel electrodes through the thin-film transistors to realize displaying of a picture for displaying the array substrate.

For example, the opposing substrate may be a color film substrate, and a color film layer corresponding to the pixel units and a black matrix covering the structures such as the gate lines and the data lines that are located in a non-display area may be provided on a side of the color film substrate facing the array substrate. For example, a common electrode disposed opposite the pixel electrode may also be provided on the side of the color film substrate facing the array substrate. The common electrode is configured to apply a common voltage to generate an electric field with the pixel electrode to drive liquid crystal molecules in the liquid crystal layer to deflect. The liquid crystal molecules are deflected to change the transmittance of the liquid crystal layer, thereby realizing the display of a desired grayscale image. For example, both the common electrode and the pixel electrode may be located on the array substrate.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A light-emitting substrate, comprising:
a substrate comprising a plurality of dimming partitions;
a plurality of light-emitting units located on the substrate; and
a light-transmission protective structure wrapping the plurality of light-emitting units, except for portions in contact with the substrate,
wherein each dimming partition comprises at least one light-emitting unit, the light-transmission protective structure comprises a plurality of sub-protective structure groups disposed in one-to-one correspondence with the plurality of dimming partitions, each sub-protective structure group wraps the light-emitting unit in one dimming partition, and adjacent sub-protective structure groups corresponding to at least two adjacent dimming partitions are integrated.

2. The light-emitting substrate according to claim 1, wherein each sub-protective structure group comprises at least one sub-protective structure, the number of the sub-protective structures is the same as the number of the plurality of light-emitting units, the sub-protective structures and the plurality of light-emitting units are disposed in one-to-one correspondence, and at least some of the sub-protective structures are integrated.

3. The light-emitting substrate according to claim 2, wherein the sub-protective structures corresponding to the same dimming partition are integrated.

4. The light-emitting substrate according to claim 2, wherein a surface of the sub-protective structure away from the substrate has a point with a greatest distance from the substrate, a distance between an orthographic projection of the point on the substrate and a center of an orthographic projection, on the substrate, of the light-emitting unit covered by the sub-protective structure is not greater than 2% of a maximum size of the orthographic projection of the light-emitting unit.

5. The light-emitting substrate according to claim 2, wherein a surface on a side that is of the integrated adjacent sub-protective structures and that is away from the substrate comprises a concave portion curving toward a side close to the light-emitting unit, and the concave portion is located between adjacent light-emitting units.

6. The light-emitting substrate according to claim 1, wherein a contour of an orthographic projection, on the substrate, of the light-transmission protective structure comprises a plurality of curved segments connected in sequence, each curved segment curves to a side away from a center of the orthographic protection of the light-transmission protective structure, and a distance between at least one endpoint of the curved segment and the center of the orthographic protection of the light-transmission protective structure is less than a distance between another point of the curved segment and the center of the orthographic protection of the light-transmission protective structure.

7. The light-emitting substrate according to claim 6, wherein at least one curved segment is an arc segment, a radius of a circle in which the arc segment is located is r, a distance between centers of adjacent light-emitting units is L, and L and r satisfy a relation equation: L/2≤r≤L.

8. The light-emitting substrate according to claim 6, wherein at least some of the curved segments are arc segments, and radii of circles where the arc segments are located are r;
the plurality of light-emitting units is arranged in an array along a first direction and a second direction, the first direction is perpendicular to the second direction, a pitch of the light-emitting units arranged in the first direction is a first pitch p1, a pitch of the light-emitting units arranged in the second direction is a second pitch p2, the first pitch is not less than the second pitch, and p1 and r satisfy a relation equation:
{[(p1)2+(p2)2]1/2}/2≤r≤p1.

9. The light-emitting substrate according to claim 5, wherein the plurality of light-emitting units is arranged in an array along a first direction and a second direction, the first direction intersects the second direction,
a minimum distance between the concave portion disposed between adjacent light-emitting units arranged in the first direction and the substrate is a first distance, a minimum distance between the concave portion disposed between adjacent light-emitting units arranged in the second direction and the substrate is a second distance, and a ratio of the first distance to the second distance is 0.95-1.05.

10. The light-emitting substrate according to claim 9, wherein the plurality of light-emitting units includes adjacent light-emitting units arranged in a third direction, the first direction and the second direction both intersect the third direction, a minimum distance between the concave portion disposed between adjacent light-emitting units arranged in the third direction and the substrate is a third distance, and the first distance is greater than the third distance.

11. The light-emitting substrate according to claim 2, wherein the plurality of light-emitting units is arranged in an array along a first direction and a second direction, the plurality of light-emitting units has a spacing in the first direction equal to that of the plurality of light-emitting units in the second direction, the plurality of sub-protective structures is of an integrated structure, and a surface of the light-transmission protective structure away from the substrate comprises a free-form surface.

12. The light-emitting substrate according to claim 1, wherein, in at least some of the dimming partitions, there is a gap between adjacent sub-protective structure groups corresponding to adjacent dimming partitions, and a surface on a side that is of the same sub-protective structure group and that is away from the substrate comprises a concave portion curving toward a side close to the light-emitting unit, and the concave portion is located between adjacent light-emitting units.

13. The light-emitting substrate according to claim 6, wherein the plurality of light-emitting units includes peripheral light-emitting units closest to the contour of the orthographic protection, on the substrate, of the light-transmission protective structure, and the number of the plurality of curved segments is the same as the number of the peripheral light-emitting units.

14. The light-emitting substrate according to claim 13, wherein the curved segments include arc segments, and degrees of central angles of circles where the arc segments are located are not greater than 280 degrees.

15. The light-emitting substrate according to claim 1, further comprising:
a reflection pattern comprising openings and a reflection layer surrounding the openings,
wherein the openings are configured to expose the light-emitting units, and along a direction perpendicular to the substrate, the reflection layer overlaps the light-transmission protective structure and is located between the light-transmission protective structure and the substrate.

16. The light-emitting substrate according to claim 15, further comprising a driver chip configured to control at least one dimming partition, the reflection layer covering the driver chip.

17. The light-emitting substrate according to claim 1, wherein a material of the light-transmission protective structure comprises organosilicon, and the light-transmission protective structure has a refractive index of 1.3-1.7 and a transmittance rate of greater than 80%;
the light-emitting unit emits light at a wavelength of 430-480 nanometers, and the light-transmission protective structure comprises an inorganic luminescent material.

18. (canceled)

19. The light-emitting substrate according to claim 1, wherein the light-emitting unit comprises an unpackaged light-emitting diode chip, and the unpackaged light-emitting diode chip has a maximum size of not greater than 500 micrometers in a direction parallel to the substrate.

20. A backlight source, comprising the light-emitting substrate according to claim 1.

21. A display apparatus, comprising the light-emitting substrate according to claim 1.
